(19) United States
(12) Patent Application Publication
(10) Pub. No.: US 2005/0093587 A1
(43) Pub. Date: May 5, 2005

(54) Frequency divider

(75) Inventors: Herbert Knapp, Munich (DE); Martin Wurzer, Munich (DE)

Correspondence Address: Maginot, Moore & Beck, Bank One Tower, Suite 3000, 111 Monument Circle, Indianapolis, IN, 46204, US

(73) Assignee: Infineon Technologies AG, Munchen (DE)

(21) Appl. No.: 10/941,745

(22) Filed: Sep. 15, 2004

(30) Foreign Application Priority Data
Sep. 15, 2003 (DE) 103 42 569.1

(51) Int. Cl. H03K 21/00

(52) U.S. Cl. 327/115

(57) ABSTRACT

A frequency divider is proposed, in which a mixer (T1-T6, 5) mixes an input signal (a, \overline{a}) with a back-coupled output signal (b, \overline{b}). Due to the use of inductors (L1, L2), a mixing amplification exhibits a band-pass characteristic. Such a circuit can also be realised in CMOS technology for operating frequencies of several tens of gigahertz.

The present invention relates to a frequency divider, such as may be used in particular for signals in the gigahertz range.

For various applications in electronics there is a need for frequency dividers for very high frequencies of up to several 10 GHz. So-called static frequency dividers can no longer be used for such high operating frequencies, and instead so-called dynamic frequency dividers are employed for this purpose. These dynamic frequency dividers include regenerative frequency dividers, which are based on active push-pull mixers, such as are discussed for example in W. D. Kasperkovitz, “Frequency-dividers for ultra-high frequencies”, Philips Tech. Rev. 38, pp. 54-68, 1978/79. These dynamic frequency dividers are normally manufactured in bipolar technique.

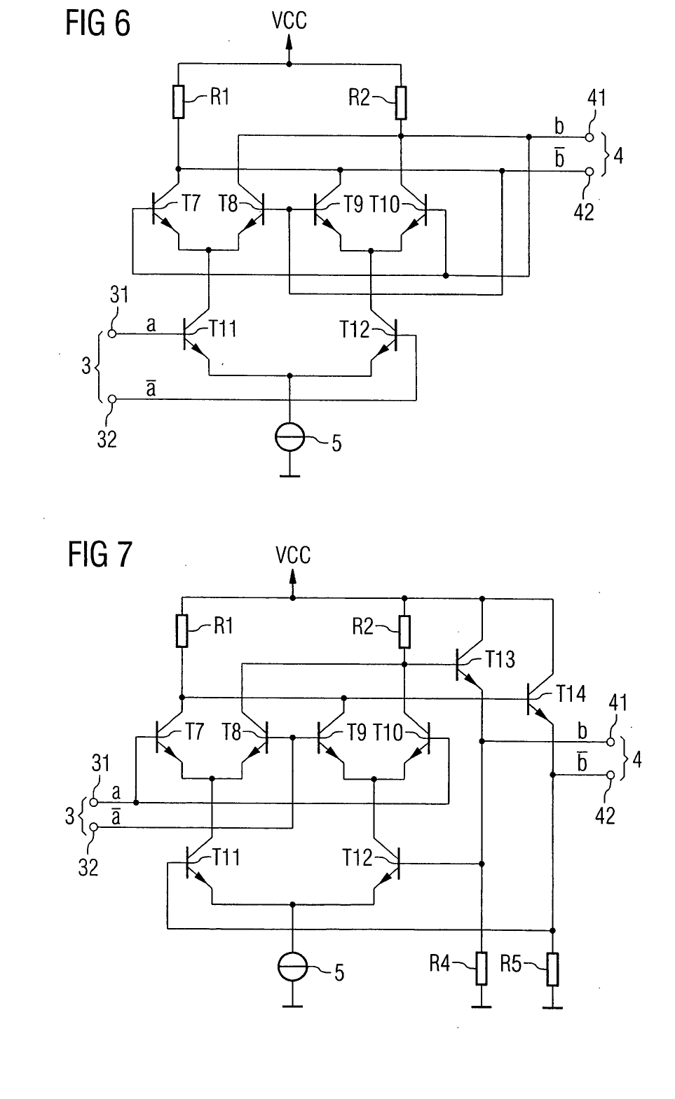

Examples of these are illustrated in FIGS. 6 and 7. The frequency divider shown in FIG. 6 consists of an active push-pull mixer, which in turn consists of three pairs of transistors T11 and T12, T7 and T8, and T9 and T10, as well as a power source 5. An input signal a is fed to a first input connection 31 and an inverted input signal \overline{a} is fed to a second input connection 31 of an input 3 of the circuit. An output signal b is tapped at a first output connection 41 at a load resistor R2, and an inverted output signal \overline{b} is tapped at a second output connection 42 at a load resistor R1. The output connections 41 and 42 form the output 4 of the frequency divider. VCC denotes a positive supply voltage.

The output signal b and the inverted output signal \overline{b} are back-coupled in the mixer at the transistors T7-T10.

The mixer is in this connection designed as an active mixer, i.e. it also acts as an amplifier. The mode of action of such a frequency divider will be described briefly hereinafter; further information may be obtained from the aforementioned article by W. D. Kasperkovitz.

It is assumed that the input signal a (also termed pump signal) is in the form cos 2ωt. Assuming that the output signal b has the form cos ωt, then the mixing of these signals produces a signal of the form ½(cos ωt+cos 3ωt). This signal is amplified by the active mixer, for example by a factor of 2. Due to the limiting frequency of the transistors T7-T12, the load resistors R1 and R2 as well as parasitic capacitors of the circuit, only a low-pass filter is now formed, which damps the component of higher frequency, i.e. the component of the form cos 3 ωt, with the result that basically an output signal of the form cos ωt is generated, which in turn is recycled to the mixer. This means that the emission of an output signal b having half the frequency of the input signal a constitutes a stable state of the frequency divider.

FIG. 7 shows a variant of the circuit of FIG. 6. Here, the output signal b and the inverted output signal \overline{b} are not tapped directly at the load resistors R2 and R1, but via the emitter follower, which consists of the transistors T13 and T14 and the resistors R4 and R5. These serve for the purposes of decoupling and level shift. Apart from this the mode of operation of the circuit of FIG. 7 is identical to the mode of operation of the circuit of FIG. 6.

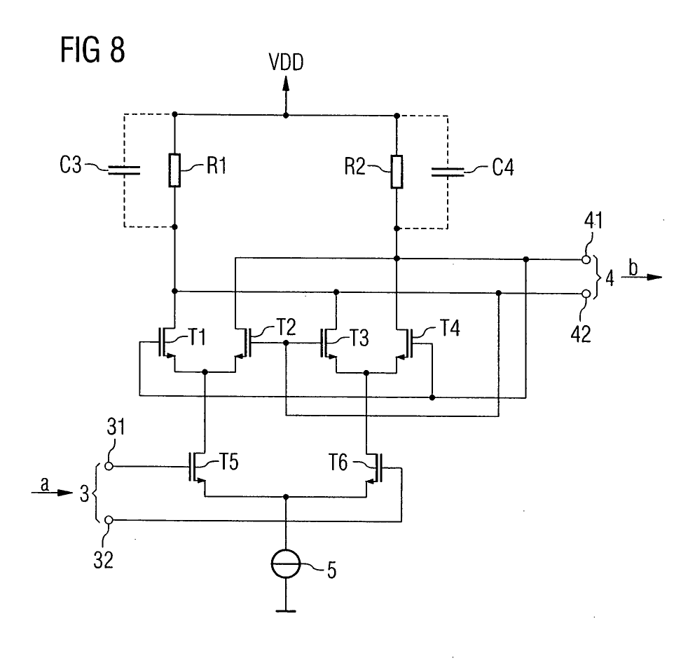

In order to achieve a high operating frequency of such a frequency divider, a high bandwidth and a high mixing amplification of the active push-pull mixer are at the same time necessary. It would be desirable to realise such dynamic frequency dividers also with MOS transistors in order to be able to produce them for example in CMOS technology. A circuit corresponding to FIG. 6 with MOS transistors T1-T6 instead of the bipolar transistors T7-T12 is shown in FIG. 8.

On account of the low transconductance of MOS transistors compared to bipolar transistors, such a direct transfer of the known circuit concept is however not promising. In order to achieve a sufficiently high mixing amplification, very high values for the operating resistors and load resistors R1 and R2 of the mixer are in fact necessary when using TMOS transistors. In conjunction with the unavoidable parasitic capacitors of the transistors and the circuit wiring (shown in dotted lines in FIG. 8 by capacitors C1 and C2) these high-ohmic load resistors R1 and R2 form a low-pass filter of low frequency. The mixing amplification therefore drops at high frequencies, resulting in a low maximal operating frequency of the frequency divider.

Additional amplifiers, in particular transimpedance amplifiers, are accordingly proposed in printed specifications DE 35 33 104 A1 and EP 0 195 299 D1. By suitable dimensioning the output impedance of such a transimpedance amplifier can exhibit an inductive characteristic. In this connection the bandwidth of the mixing amplification compared to the conventional circuit illustrated in FIG. 6 or FIG. 8 can be increased by resonance rise. When using CMOS technology the bandwidth that can thereby be obtained is however still not sufficient to achieve high operating frequencies. In addition, due to the use of an additional amplifier an increased circuit complexity and a higher supply voltage are necessary.

An object of the present invention is accordingly to provide a frequency divider that is also suitable for high frequencies in the range of several 10 GHz, which can be realised in CMOS technology, and which is simple in design and construction.

This object is achieved by a frequency divider according to claim 1 and a frequency divider according to claim 14. The dependent claims define advantageous or preferred embodiments of the frequency divider.

The frequency divider according to the invention comprises a frequency mixer, wherein an input signal can be fed to the frequency mixer, wherein an output signal can be tapped at an output of the frequency divider, and wherein the output signal is back-coupled to the frequency mixer for mixing with the input signal. According to the invention the frequency divider also comprises band-pass filtering means 2 connected between an output of the frequency mixer 1 and the output of the frequency mixer. By using a band-pass filter instead of the conventional low-pass filter, the operating frequency can be shifted to higher ranges, especially when using CMOS transistors.

As an alternative to the provision of a band-pass filter described above, at least one inductor can be connected as load to the output of the frequency mixer.

Preferably the at least one inductor is designed so that a resonance circuit formed by the at least one inductor and at least one capacitor of the frequency mixer, for example a parasitic capacitor, has a maximum impedance around a frequency that corresponds to half the frequency of the input signal. By this means the mixing amplification for signals of half the frequency of the input signal is large, and a frequency division by a factor of 2 is achieved. In this connection the operating frequency of the frequency divider may amount to several 10 GHz also when using CMOS technology.

The frequency mixer is in this connection preferably designed as an active mixer and comprises a push-pull mixer.

The at least one inductor may comprise a plurality of inductors and additional capacitors in order to broaden the bandwidth of the frequency divider.

Preferably the input signal as well as the inverted input signal can be fed to the input, and the output signal as well as the inverted output signal can then be tapped at the output.

The frequency divider according to the invention may be constructed partially or wholly with MOS transistors, in particular in CMOS technology, and in principle the circuit arrangement according to the invention is however also suitable for realisation with bipolar transistors or HBT transistors. The frequency divider may be designed as an integrated circuit.

The invention is described in more detail hereinafter with the aid of preferred examples of implementation and with reference to the accompanying drawings, in which:

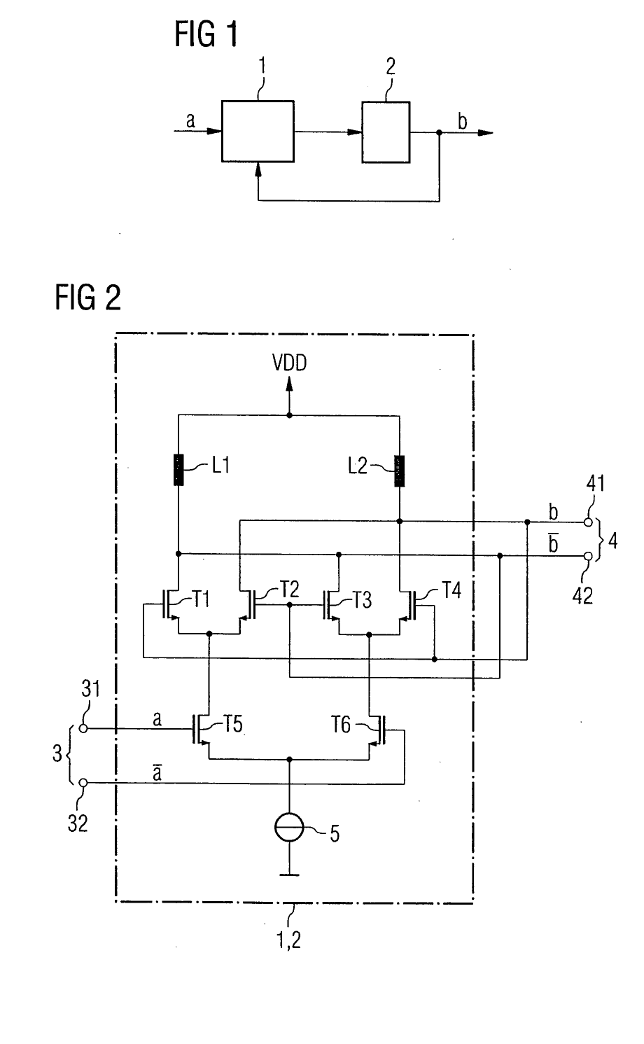

FIG. 1 is a block diagram of an example of implementation of a frequency divider according to the invention,

FIG. 2 is a circuit technology realisation of a further example of implementation of a frequency divider according to the invention,

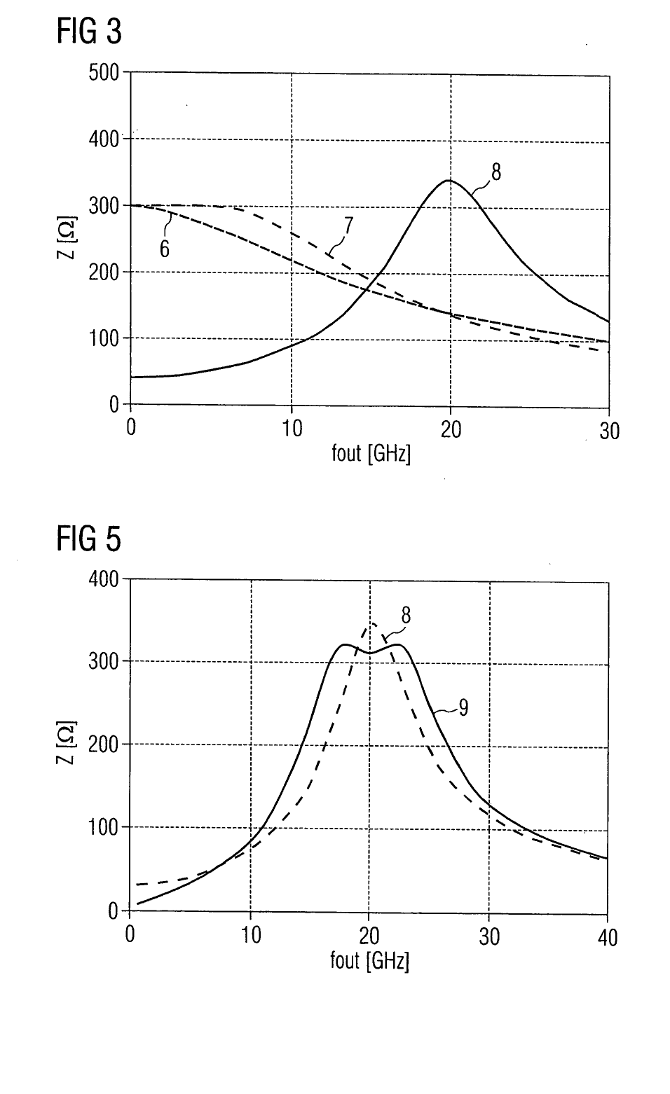

FIG. 3 is a comparison of the load impedance of the frequency divider according to the invention of FIG. 2 with conventional frequency dividers,

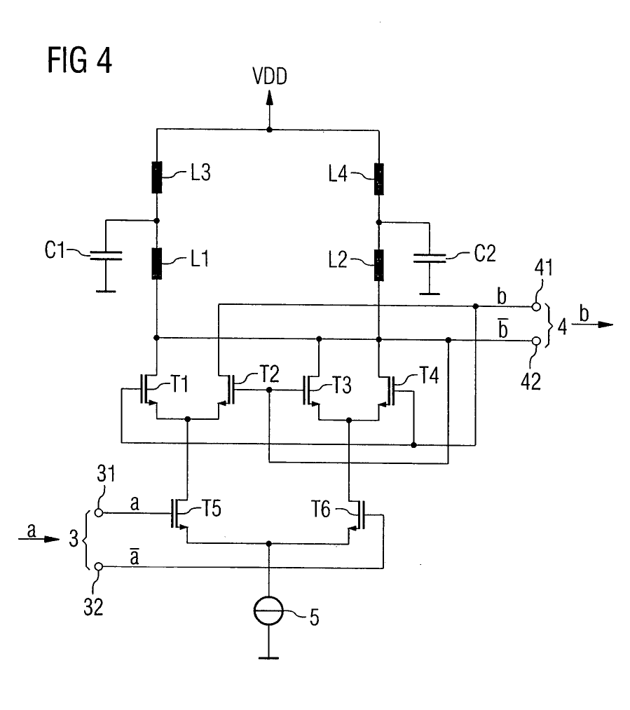

FIG. 4 is a modification of the example of implementation of FIG. 2,

FIG. 5 is a comparison of the load impedance of the example of implementation of FIG. 2 with the modified example of implementation of FIG. 4,

FIG. 6 shows a conventional frequency divider,

FIG. 7 shows a further conventional frequency divider, and

FIG. 8 is a transfer of the conventional frequency divider from FIG. 6 to a circuit with MOS transistors.

A block circuit diagram of a first example of implementation of the invention is shown in FIG. 1. In this, an input signal a is fed to a mixer 1 and the output signal of the mixer is band-pass-filtered by a band-pass filter 2.

The output signal b is thereby generated, which is back-coupled in the mixer 1 for mixing with the input signal a.

The basic mode of operation of this arrangement corresponds to that in the introduction to the description with reference to FIG. 6, in which a band-pass filter is provided instead of the conventional low-pass filter. This means that, for a division of the frequency of the input signal a by two, the band-pass filter 2 is designed so that it lets signals with this halved frequency pass, and thus in particular suppresses the components of the mixed signal of higher frequency as explained in the introduction to the description.

A band-pass filter may, as explained in more detail hereinafter, be designed in a simple way for higher frequencies than the conventionally used low-pass filter. In addition, with a sufficiently large amplitude of the input signal a mixing with harmonics of the input signal is possible. This effect is undesired in conventional regenerative frequency dividers since it leads to interference on account of the low-pass characteristic of the mixing amplification. In the case of the example of implementation of FIG. 1 a band-pass filter is however used, whereby it is possible selectively to amplify a desired mixing product with a desired frequency. This may be utilised for example to achieve a higher division factor than a frequency division by a factor of 2. For example, the frequency of the input signal a can be divided by four, by adapting the band-pass filter to a frequency of ¾ of the frequency of the input signal.

As will be shown hereinafter, it is however not necessary to provide the band-pass filter as a separate stage. Instead, it is possible in a simple manner to realise a mixing amplifier having a band-pass characteristic.

A circuit technology realisation of such a second example of implementation of the present invention is shown in FIG. 2. The illustrated circuit corresponds substantially to the circuit already described in the introduction to the description with reference to FIG. 6.

At an input 3 the input signal a can be fed to a first input connection 31, and at an input connection 32 an inverted input signal \overline{a} can be fed to an active mixing amplifier. In the present example of implementation this is composed of six MOS transistors T1-T6 as well as a power source 5. The function of the MOS transistors T1-T6 corresponds to that of the bipolar transistors T7-T12 of FIG. 6 explained in the introduction to the description. At an output 4 the output signal b can be tapped at a first output connection 41, and an inverted output signal \overline{b} can be tapped at a second output connection 42. The output signal is back-coupled via the transistors T1-T4 in the mixer for mixing with the input signal a or with the inverted input signal \overline{a}. The transistors T1-T6 are in this connection connected as shown in FIG. 2 to form three pairs of transistors T1 and T2, T3 and T4, and T5 and T6.

In contrast to the conventional circuit shown in FIG. 6, the load resistors R1 and R2 are replaced by load inductors L1 and L2, which in each case connect an output connection 41, 42 to a positive supply voltage VDD. They may be integrated for example in the form of spiral inductors together with the transistors on a semiconductor chip. Together with parasitic capacitors of the wiring and the MOS transistors T1-T6 they comprise a parallel resonance circuit that forms a high load impedance for the desired frequency. High operating frequencies of the frequency divider are thus made possible.

FIG. 3 shows the curve of the load impedance, here identified by Z, in ohms, plotted against the output frequency fout of the output signal b in gigahertz. The curve 6 describes the behaviour of the output impedance of a conventional frequency divider as shown in FIG. 6. The low-pass characteristic can clearly be seen, in other words a drop in the load impedance and thus also of the mixing amplification at high frequencies. Curve 7 shows the behaviour of the load impedance when using a transimpedance amplifier, as is the case in DE 35 33 104 A1 already cited in the introduction. Due to the use of the amplifier the drop in the amplification is shifted to somewhat higher frequencies. However, for many applications this is still not sufficient. Curve 8 shows the behaviour of the load impedance Z with the frequency divider of FIG. 2 according to the invention. A maximum of the load impedance and thus also of the mixing amplification clearly occurs at a frequency of about 20 GHz. This is substantially higher than the values that can be realised with conventional circuits. Thus, by using a circuit according to the invention a significantly higher operating frequency can also be achieved with MOS transistors.

FIG. 4 shows a circuit that is expanded compared to that illustrated in FIG. 2. The active push-pull mixer, composed of the transistors T1-T6 and the power source 5, remains unchanged. Instead of being connected in each case to an inductor, the output connections 41 and 42 are now connected in each case via two inductors L1 and L3 or L2 and L4 to the positive supply voltage VDD. A connection to a capacitor C1 and C2 is provided between the inductors L1 and L3 and L2 and L4, the capacitors in each case being earthed through their other connection.

A larger bandwidth of the resonance circuit can be achieved with such a circuit arrangement. This is illustrated in FIG. 5. Again, the magnitude of the load impedance Z in ohms is plotted against the output frequency, i.e. the frequency of the output signal b, in GHz. Curve 8 shows in turn the behaviour of the output impedance of a circuit as illustrated in FIG. 2, while curve 9 shows the behaviour of the load impedance of the circuit illustrated in FIG. 4. A broadening of the maximum can clearly be seen, corresponding to a larger bandwidth of the amplification.

As already mentioned, the circuit concept according to the invention illustrated here may be employed particularly advantageously in circuits using CMOS technology. A realisation with other technologies, for example with bipolar transistors or HEMTS (“High Electron Mobility Transistors”) is however also possible.

Furthermore, it is conceivable to expand the circuit similarly to FIG. 7, in other words to tap the output signal not directly at the inductors, but to use for example source followers, similarly to the emitter followers of FIG. 7.

Obviously the principle according to the invention may basically also be used with frequency mixers other than the active push-pull mixers illustrated here.

1-16. (canceled)

17. A frequency divider comprising:
at least one input operable to receive an input signal;
a frequency mixer connected to the at least one input and operable to receive the input signal;
at least one output operable to provide an output signal, the at least one output connected to the frequency mixer such that the output signal is back-coupled to the frequency mixer and mixed with the input signal; and
at least one inductor connected to the at least one output as a load to the output.

18. The frequency divider of claim 17 further comprising a supply voltage and wherein the at least one inductor connects the output to the supply voltage.

19. The frequency divider of claim 17 wherein the frequency mixer comprises at least one capacitor, and wherein the at least one inductor is designed such that a resonance circuit formed by the at least one inductor and the at least one capacitor of the frequency mixer has a maximum impedance around a frequency that corresponds to half the frequency of the input signal.

20. The frequency divider of claim 19, wherein the at least one capacitor is formed by at least one parasitic capacitor of the frequency mixer.

21. The frequency divider of claim 17 wherein the frequency mixer comprises a push-pull mixer.

22. The frequency divider of claim 17 wherein the frequency mixer is designed as an active mixer.

23. The frequency divider of claim 17,
wherein the output is connected to a first connection of a first inductor,
wherein a second connection of the first inductor is connected to a first connection of a second inductor and to a first connection of a capacitor,
wherein a second connection of the capacitor is connected to a first potential, and
wherein a second connection of the second inductor is connected to a second potential.

24. The frequency divider of claim 17 wherein the input signal is fed to a first input connection and an inverted input signal is fed to a second input connection, and at the output of the frequency divider the output signal can be tapped at a first output connection and the inverted output signal can be tapped at a second output connection.

25. The frequency divider of claim 24 wherein the first output connection and the second output connection are in each case connected as a load to the at least one inductor.

26. The frequency divider of claim 24,
wherein the first input connection is connected to a control connection of a first transistor,
wherein the second input connection is connected to a control connection of a second transistor,
wherein a first connection of the first transistor is connected to a corresponding first connection of the second transistor and to a power source,
wherein a second connection of the first transistor is connected to a first connection of a third transistor and to a corresponding first connection of a fourth transistor,
wherein a second connection of the second transistor is connected to a first connection of a fifth transistor and to a corresponding first connection of a sixth transistor,
wherein a control connection of the third transistor is connected to a control connection of the sixth transistor, to a second connection of the fourth transistor, to a second connection of the sixth transistor and to the first output connection, and
wherein a control connection of the fourth transistor is connected to a control connection of the fifth transistor, to a second connection of the third transistor, to a second connection of the fifth transistor and to the second output connection.

27. The frequency divider of claim 26 wherein at least one of the first to sixth transistors is an MOS transistor.

28. The frequency divider of claim 26 wherein at least one of the first to sixth transistors is a bipolar transistor.

29. The frequency divider of claim 17 wherein the at least one inductor is a spiral inductor.

30. The frequency divider of claim 17 wherein the frequency divider is designed as an integrated circuit.

31. A frequency divider comprising:
an input operable to receive an input signal;
a frequency mixer connected to the input and operable to receive the input signal, the frequency mixer comprising a frequency mixer output;
a frequency divider output operable to provide an output signal, the frequency divider output connected to the frequency mixer such that the output signal is back-coupled to the frequency mixer and mixed with the input signal; and
a band-pass filter connected between the frequency mixer output and the frequency divider output.

32. The frequency divider of claim 31 wherein the band-pass filter comprises at least one inductor connected to the frequency mixer output.

33. The frequency divider of claim 32 further comprising a supply voltage and wherein the at least one inductor connects the output to the supply voltage.

34. The frequency divider of claim 31 wherein the frequency mixer comprises a push-pull mixer.

35. The frequency divider of claim 31 wherein the frequency mixer is designed as an active mixer.

36. The frequency divider of claim 31 wherein the input signal is fed to a first input connection and an inverted input signal is fed to a second input connection, and at the output of the frequency divider the output signal can be tapped at a first output connection and the inverted output signal can be tapped at a second output connection.
